(19) United States
(12) Patent Application Publication
(10) Pub. No.: US 2019/0048467 A1
(43) Pub. Date: Feb. 14, 2019

(54) SHOWERHEAD AND PROCESS CHAMBER INCORPORATING SAME

(71) Applicant: APPLIED MATERIALS, INC., Santa Clara, CA (US)

(72) Inventors: MARIO DAN SANCHEZ, San Jose, CA (US); MUHAMMAD M. RASHEED, San Jose, CA (US)

(21) Appl. No.: 15/847,339

(22) Filed: Dec. 19, 2017

Related U.S. Application Data
(60) Provisional application No. 62/543,888, filed on Aug. 10, 2017.

(51) Int. Cl. C23C 16/455

(52) U.S. Cl. CPC C23C 16/45565; C23C 16/4405; C23C 16/45502; C23C 16/45544

(57) ABSTRACT

Showerheads and process chambers incorporating same are provided herein. In some embodiments, a showerhead includes a body having a central portion and an outer portion, wherein the outer portion includes an annular wall extending upward from the central portion and a flange extending radially outward from the annular wall; a plurality of apertures disposed through the central portion; an annular stepped portion disposed radially outward of outermost ones of the plurality of apertures and radially inward of the outer portion; a plurality of positioning features arranged about a central axis of the showerhead and formed in a periphery of the outer portion; and a plurality of coupling features arranged about the central axis and formed in the periphery of the outer portion.

### CROSS-REFERENCE TO RELATED APPLICATIONS

This application claims benefit of U.S. provisional patent application Ser. No. 62/543,888, filed Aug. 10, 2017, which is herein incorporated by reference in its entirety.

### FIELD

Embodiments of the disclosure generally relate to a showerhead and a process chamber incorporating same.

### BACKGROUND

Reliably producing submicron and smaller features is one of the key technologies for the next generation of very large scale integration (VLSI) and ultra large scale integration (ULSI) of semiconductor devices. However, as the fringes of circuit technology are pressed, the shrinking dimensions of interconnects in VLSI and ULSI technology have placed additional demands on the processing capabilities. The multilevel interconnects that lie at the heart of VLSI and ULSI technology use precise processing of high aspect ratio features, such as vias and other interconnects. Reliable formation of these interconnects is very important to VLSI and ULSI success and to the continued effort to increase circuit density and quality of individual substrates.

As circuit densities increase, the widths of interconnects, such as vias, trenches, contacts, and other features, as well as the dielectric materials between, decrease while the thickness of the dielectric layers remain substantially constant, resulting in increased height-to-width aspect ratios of the features. Many traditional deposition processes have difficulty filling submicron structures where the aspect ratio exceeds 4:1, and particularly where the aspect ratio exceeds 10:1. Therefore, there is a great amount of ongoing effort being directed at the formation of substantially void-free and seam-free submicron features having high aspect ratios.

Atomic layer deposition (ALD) is a deposition technique being explored for the deposition of material layers over features having high aspect ratios. One example of an ALD process includes the sequential introduction of pulses of gases. For instance, one cycle for the sequential introduction of pulses of gases may contain a pulse of a first reactant gas, followed by a pulse of a purge gas and/or a pump evacuation, followed by a pulse of a second reactant gas, and followed by a pulse of a purge gas and/or a pump evacuation. The term “gas” as used herein is defined to include a single gas or a plurality of gases. Sequential introduction of separate pulses of the first reactant and the second reactant may result in the alternating self-limiting absorption of monolayers of the reactants on the surface of the substrate and, thus, forms a monolayer of material for each cycle. The cycle may be repeated to a desired thickness of the deposited material. A pulse of a purge gas and/or a pump evacuation between the pulses of the first reactant gas and the pulses of the second reactant gas serves to reduce the likelihood of gas phase reactions of the reactants due to excess amounts of the reactants remaining in the chamber.

In some chamber designs for ALD processing, precursors and gases are delivered using a funnel lid through which precursor is distributed through multiple injectors above a funnel shaped lid. The injectors generate a circular motion of the injected gas which distributes through the funnel profile at the center of the lid. The rotational inertia of the gas/ALD precursor molecules distributes the molecules from center to edge resulting in improved uniformity deposition. However, in some applications, the inventors have observed a donut-shaped deposition profile near the center of the substrate being processed. The donut-shaped deposition profile is believed to be caused by the funnel shape of the lid and can lead to integration issues for customers.

Therefore, the inventors have provided improved showerheads for use in a substrate processing chamber.

### SUMMARY

Showerheads and process chambers incorporating same are provided herein. In some embodiments, a showerhead includes a body having a central portion and an outer portion, wherein the outer portion includes an annular wall extending upward from the central portion and a flange extending radially outward from the annular wall; a plurality of apertures disposed through the central portion; an annular stepped portion disposed radially outward of outermost ones of the plurality of apertures and radially inward of the outer portion; a plurality of positioning features arranged about a central axis of the showerhead and formed in a periphery of the outer portion, wherein the plurality of positioning features are configured to receive a corresponding plurality of alignment features of a process chamber in which the showerhead is installed, and wherein the plurality of positioning features are configured to allow for thermal expansion of the showerhead; and a plurality of coupling features arranged about the central axis and formed in the periphery of the outer portion, wherein the plurality of coupling features are configured to receive a corresponding plurality of fixation elements to couple the showerhead to the process chamber, and wherein the plurality of coupling features are configured to allow for thermal expansion of the showerhead.

In some embodiments, a showerhead includes a body having a central portion and an outer portion, wherein the outer portion includes an annular wall extending upward from the central portion and a flange extending radially outward from the annular wall; a plurality of apertures disposed through the central portion; an annular stepped portion disposed radially outward of outermost ones of the plurality of apertures and radially inward of the outer portion; a plurality of positioning features arranged about a central axis of the showerhead and formed in a periphery of the outer portion, wherein the plurality of positioning features are configured to receive a corresponding plurality of alignment features of a process chamber in which the showerhead is installed, and wherein the plurality of positioning features are configured to allow for thermal expansion of the showerhead; and a plurality of coupling features arranged about the central axis and formed in the periphery of the outer portion, wherein the plurality of coupling features are configured to receive a corresponding plurality of fixation elements to couple the showerhead to the process chamber, and wherein the plurality of coupling features are configured to allow for thermal expansion of the showerhead, wherein an overall outer diameter of the showerhead is between about 16 inches and about 17.5 inches, wherein an overall height of the showerhead is between about 1 inch and about 1.5 inches, wherein a vertical thickness of the flange is between about 0.5 inches and about 0.6 inches, wherein a vertical distance from a first uppermost surface of the flange to a second uppermost surface of the annular stepped portion is between about 0.5 inches and about 1 inch, and wherein a thickness of the central portion is between about 0.2 inches and about 0.5 inches.

In some embodiments, a showerhead includes a body having a central portion and an outer portion, wherein the outer portion includes an annular wall extending upward from the central portion and a flange extending radially outward from the annular wall; a plurality of apertures disposed through the central portion; an annular stepped portion disposed radially outward of outermost ones of the plurality of apertures and radially inward of the outer portion; a plurality of positioning features arranged about a central axis of the showerhead and formed in a periphery of the outer portion, wherein the plurality of positioning features are configured to receive a corresponding plurality of alignment features of a process chamber in which the showerhead is installed, and wherein the plurality of positioning features are configured to allow for thermal expansion of the showerhead; and a plurality of coupling features arranged about the central axis and formed in the periphery of the outer portion, wherein the plurality of coupling features are configured to receive a corresponding plurality of fixation elements to couple the showerhead to the process chamber, and wherein the plurality of coupling features are configured to allow for thermal expansion of the showerhead, wherein an overall outer diameter of the showerhead is between about 16 inches and about 17.5 inches, wherein an overall height of the showerhead is between about 1 inch and about 1.5 inches, wherein a vertical thickness of the flange is between about 0.5 inches and about 0.6 inches, wherein a vertical distance from a first uppermost surface of the flange to a second uppermost surface of the annular stepped portion is between about 0.5 inches and about 1 inch, and wherein a thickness of the central portion is between about 0.2 inches and about 0.5 inches, wherein a first inner diameter of the annular stepped portion is between about 12 inches and about 13 inches, wherein a second inner diameter of the annular wall is between about 12.5 inches and about 13.5 inches, and wherein an outer diameter of a lowermost surface of the central portion is between about 13.5 inches and about 14.5 inches.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, that the appended drawings illustrate only typical embodiments of the disclosure and are therefore not to be considered limiting of scope, for the disclosure may admit to other equally effective embodiments.

FIG. 1 depicts a schematic view of a process chamber in accordance with some embodiments of the present disclosure.

FIG. 2 depicts a schematic cross-sectional view of a showerhead in accordance with some embodiments of the present disclosure.

FIG. 3A depicts a schematic cross-sectional view of a portion of a lid assembly in accordance with some embodiments of the present disclosure.

FIG. 3B depicts a close-up view of Section 3B of FIG. 3A.

FIG. 4A depicts a top schematic view of a showerhead in accordance with some embodiments of the present disclosure.

FIG. 4B depicts a close-up view of Section 4B of FIG. 4A.

FIG. 4C depicts a close-up view of Section 4C of FIG. 4A.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure provide showerheads that may be used in substrate processing chambers, such as, for example, an atomic layer deposition (ALD) chamber during, for example, an ALD process. Embodiments include substrate processing chambers and gas delivery systems which include a remote plasma source and a gas distribution plate. Other embodiments provide methods for depositing materials using these gas delivery systems during ALD processes. Examples of suitable processing chambers for incorporation of the apparatuses described herein include high dielectric constant (i.e., high k) and metal ALD deposition chambers available from Applied Materials, Inc., of Santa Clara, Calif. The following process chamber description is provided for context and exemplary purposes, and should not be interpreted or construed as limiting the scope of the disclosure.

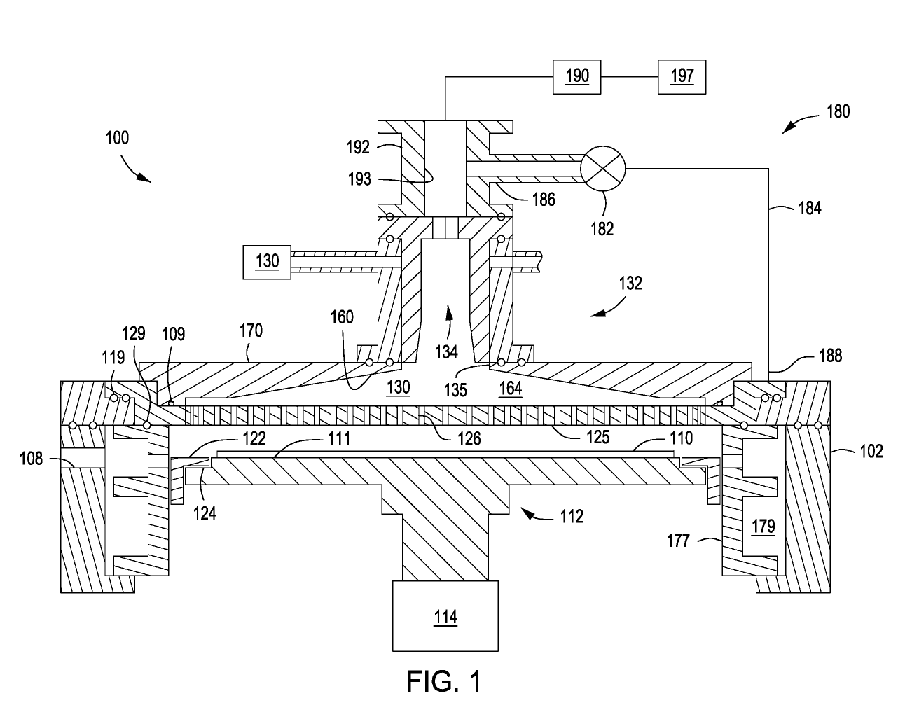

The following description is made with reference to FIGS. 1 and 3A. FIG. 1 is a schematic view of a substrate processing chamber (process chamber 100) including a showerhead 125 in accordance with some embodiments of the present disclosure. FIG. 3A is a schematic cross-sectional close-up view of the showerhead 125 disposed within the process chamber 100. Process chamber 100 includes a chamber body 102 having a processing volume within the chamber body 102 and beneath the chamber lid assembly 132. Slit valve 108 in the process chamber 100 provides access for a robot (not shown) to deliver and retrieve a substrate 110, such as a 200 mm or 300 mm semiconductor wafer or a glass substrate, to and from the process chamber 100. A chamber liner 177 is disposed along the walls of the process chamber 100 to protect the chamber from corrosive gases used during processing/cleaning.

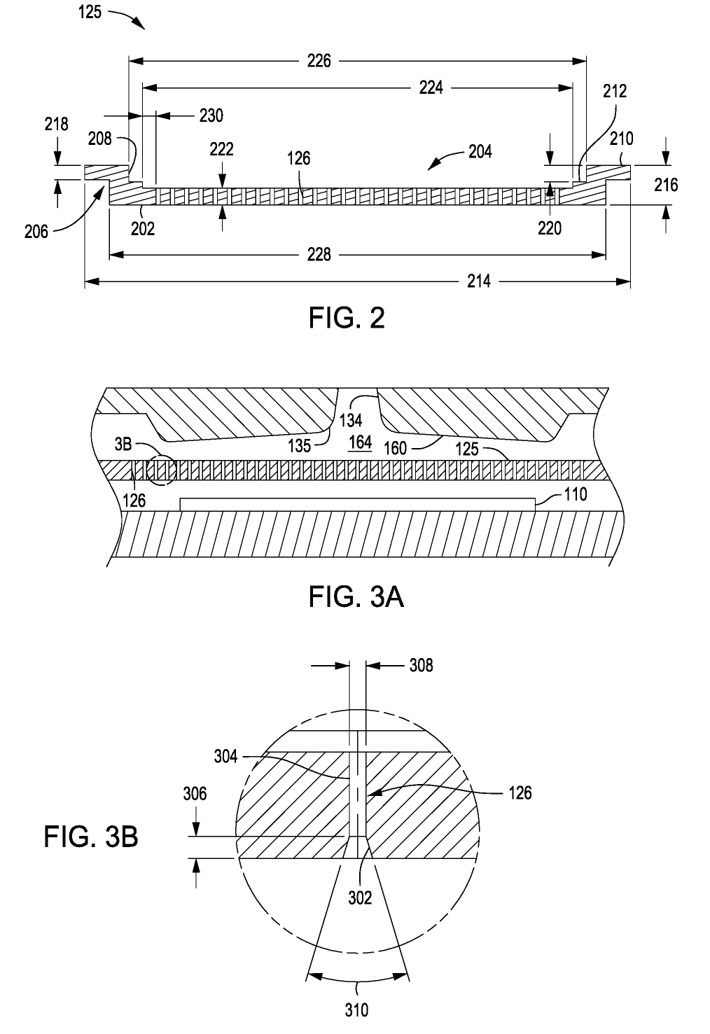

A substrate support 112 supports the substrate 110 on a substrate receiving surface 111 in the process chamber 100. The substrate support 112 is mounted to a lift motor 114 for raising and lowering the substrate support 112 and the substrate 110 disposed on the substrate support. A lift plate 116 (shown in FIG. 2), connected to a lift motor 118, is mounted in the process chamber 100 to raise and lower lift pins 120 movably disposed through the substrate support 112. The lift pins 120 raise and lower the substrate 110 over the surface of the substrate support 112. The substrate support 112 may include a vacuum chuck (not shown), an electrostatic chuck (not shown), or a clamp ring (not shown) for securing the substrate 110 to the substrate support 112 during a deposition process.

The temperature of the substrate support 112 may be adjusted to control the temperature of the substrate 110. For example, substrate support 112 may be heated using an embedded heating element, such as a resistive heater (not shown), or may be heated using radiant heat, such as heating lamps (not shown) disposed above the substrate support 112. A purge ring 122 may be disposed on the substrate support 112 to define a purge channel 124 which provides a purge gas to a peripheral portion of the substrate 110 to prevent deposition on the peripheral portion of the substrate 110.

Gas delivery system 130 is disposed at an upper portion of the chamber body 102 to provide a gas, such as a process gas and/or a purge gas, to process chamber 100. A vacuum system (not shown) is in communication with a pumping channel 179 to evacuate any desired gases from the process chamber 100 and to help maintain a desired pressure or pressure range inside the process chamber 100.

In some embodiments, the chamber lid assembly 132 includes a gas dispersion channel 134 extending through a central portion of the chamber lid assembly 132. The gas dispersion channel 134 extends perpendicularly toward the substrate receiving surface 111 and also extends along a central axis 133 of the gas dispersion channel 134, through lid plate 170, and to lower surface 160. In some embodiments, an upper portion of the gas dispersion channel 134 is substantially cylindrical along central axis 133 and a lower portion of the gas dispersion channel 134 tapers away from central axis 133. The lower surface 160 is sized and shaped to substantially cover the substrate 110 disposed on the substrate receiving surface 111 of the substrate support 112. The lower surface 160 tapers from an outer edge of the lid plate 170 towards the gas dispersion channel 134. The gas delivery system 130 may provide one or more gasses to the gas dispersion channel 134 to process the substrate 110. In some embodiments, the gas delivery system 130 may be coupled to the gas dispersion channel 134 via one gas inlet. In some embodiments, the gas delivery system may alternatively be coupled to the gas dispersion channel 134 via a plurality of inlets.

In some embodiments, circular gas flow through the gas dispersion channel 134 can lead to non-uniform processing results. The inventors have observed the gas flow may lead to a donut-shaped deposition profile near a center of the substrate 110 being processed. The donut-shaped profile may be caused by the funnel shape of gas dispersion channel 134. Therefore, in some embodiments, the process chamber 100 further includes a showerhead 125 having a plurality of apertures 126 disposed through the showerhead 125. The showerhead 125 extends over the surface of the gas dispersion channel 134 such that the only pathway from the gas dispersion channel 134 to the substrate is through the plurality of apertures 126 of the showerhead 125. The showerhead 125 advantageously creates a choked flow of gas through the showerhead 125 resulting in a more uniform deposition on the substrate 110 and, thus, substantially eliminating the donut-shaped deposition caused by the rotational flow of gas.

In some embodiments, the showerhead 125 is formed of aluminum, stainless steel, or a ceramic material such as, for example, aluminum oxide or aluminum nitride. In some embodiments, each of the plurality of apertures 126 may have an equivalent fluid conductance. In some embodiments, a density of the plurality of apertures 126 (e.g., the number of apertures or the size of the openings of the apertures per unit area) may vary across the showerhead 125 to achieve a desired deposition profile on the substrate 110. For example, a higher density of apertures 126 may be disposed at a center of the showerhead 125 to increase the deposition rate at the center of the substrate relative to the edge of the substrate to further improve deposition uniformity. In some embodiments, the density of the plurality of apertures 126 may alternatively be the same across the showerhead 125. In some embodiments, the number of apertures 126 may be between about 1,000 and about 3,000. The inventors have discovered fewer than 1,000 apertures would result in process non-uniformities due to over-compressing of the process gas and not enough distribution of the process gas. In addition, fewer apertures would also lead to increased process time because pumping and purging of the area above the showerhead 125 would require more time. The inventors have also discovered that more than 3,000 apertures would negatively impact process gas distribution because the apertures would not sufficiently choke the process gas flowing through the showerhead 125. In some embodiments the outermost ones of the plurality of apertures 126 are disposed at or outside of a diameter of the substrate 110.

Although the plurality of apertures 126 are depicted as cylindrical through holes in FIGS. 1-3A, the plurality of apertures 126 may have different profiles, as shown in FIG. 3B and discussed below. Not wishing to be bound by theory, the inventors believe that the diameter of gas dispersion channel 134, which is constant from the upper portion of gas dispersion channel 134 to a first point along central axis 133 and increasing from the first point to lower portion 135 of gas dispersion channel 134, allows less of an adiabatic expansion of a gas through gas dispersion channel 134 which helps to control the temperature of the process gas contained in the circular gas flow 174. For example, a sudden adiabatic expansion of a gas delivered into gas dispersion channel 134 may result in a drop in the temperature of the gas which may cause condensation of the gas and formation of droplets. On the other hand, a gas dispersion channel 134 that gradually tapers is believed to provide less of an adiabatic expansion of a gas. Therefore, more heat may be transferred to or from the gas, and, thus, the temperature of the gas may be more easily controlled by controlling the temperature of chamber lid assembly 132. Gas dispersion channel 134 may gradually taper and contain one or more tapered inner surfaces, such as a tapered straight surface, a concave surface, a convex surface, or combinations thereof or may contain sections of one or more tapered inner surfaces (i.e., a portion tapered and a portion non-tapered).

In some embodiments, the process chamber 100 further includes a chamber cleaning system including a remote plasma source (RPS) 190, an isolation collar 192 coupled to the RPS 190, and a cleaning gas (i.e., purge gas) source 197 fluidly coupled to the RPS 190. The cleaning gas source may include any gas suitable for forming a plasma to clean the process chamber 100. The isolation collar 192 includes an inner channel 193 that is fluidly coupled to the gas dispersion channel 134 to flow a plasma from the RPS 190 through the gas dispersion channel 134 and into the reaction zone 164.

Typically, a cleaning gas is flowed through the gas dispersion channel 134 and the reaction zone 164 after a first gas is provided to the gas dispersion channel 134 by the gas delivery system 130 to quickly purge the first gas from the gas dispersion channel 134 and the reaction zone 164. Subsequently, a second gas is provided by the gas delivery system 130 to the gas dispersion channel 134 and the cleaning gas is again flowed through the gas dispersion channel 134 to the reaction zone 164 to quickly purge the second gas from the gas dispersion channel 134 and the reaction zone 164. In some embodiments, an exhaust system 180 having an exhaust conduit 184 is coupled to the isolation collar 192 at a first end 186 and to the pumping channel 179 at a second end 188. A valve 182 is disposed in the exhaust conduit 184 to selectively fluidly couple the exhaust conduit 184 to the inner channel 193. Each time the cleaning gas is flowed through the gas dispersion channel 134 and the reaction zone 164, the valve 182 is opened and the cleaning gas is rapidly exhausted to the pumping channel 179.

In some embodiments, a portion of lower surface 160 of chamber lid assembly 132 may be contoured or angled downwardly and outwardly from a central opening coupled to the gas dispersion channel 134 to a peripheral portion of chamber lid assembly 132 to help provide an improved velocity profile of a gas flow from gas dispersion channel 134 across the surface of substrate 110 (i.e., from the center of the substrate to the edge of the substrate). Lower surface 160 may contain one or more surfaces, such as a straight surface, a concave surface, a convex surface, or combinations thereof. In one embodiment, lower surface 160 is convexly funnel-shaped.

In one example, lower surface 160 is downwardly and outwardly sloping toward an edge of the substrate receiving surface 111 to help reduce the variation in the velocity of the process gases traveling between lower surface 160 of chamber lid assembly 132 and substrate 110 while assisting to provide uniform exposure of the surface of substrate 110 to a reactant gas. The components and parts of chamber lid assembly 132 may contain materials such as stainless steel, aluminum, nickel-plated aluminum, nickel, alloys thereof, or other suitable materials. In one embodiment, lid plate 170 may be independently fabricated, machined, forged, or otherwise made from a metal, such as aluminum, an aluminum alloy, steel, stainless steel, alloys thereof, or combinations thereof. The process chamber 100 may further include a first seal 109 disposed between the showerhead 125 and the lid plate 170, a second seal 119 disposed between the showerhead 125 and the chamber body 102 or an adapter disposed between the chamber body 102 and the showerhead 125, and a third seal 129 disposed between the showerhead 125 and the chamber liner 177. In some embodiments, the first, second, and third seals 109, 119, 129 may be o-rings.

FIG. 2 shows a schematic cross-sectional view of the showerhead 125 in accordance with some embodiments of the present disclosure. As illustrated in FIG. 2, the showerhead 125 may include a body 202 having a central portion 204 and an outer portion 206. The outer portion 206 includes an annular wall 208 extending upward from the central portion 204 and a flange 210 extending radially outward from the annular wall 208. The plurality of apertures 126 are disposed through the central portion 204. In some embodiments, an annular stepped portion 212 is disposed radially outward of outermost ones of the plurality of apertures 126 and radially inward of the outer portion 206. The annular stepped portion 212 serves as a support surface for the first seal 109.

In some embodiments, an overall outer diameter 214 of the showerhead 125 is between about 16 inches and about 17.5 inches. The inventors have discovered that if the showerhead 125 has an overall outer diameter 214 smaller than about 16 inches, a gap will exist between the showerhead 125 and the adjacent chamber component, resulting in an additional volume that would need to be purged and pumped down. As a result, throughput would be negatively impacted due to increased process time. Conversely, if the overall outer diameter 214 of the showerhead 125 is too large, an interference fit will exist between the showerhead 125 and the adjacent chamber component, which would interfere with thermal expansion of the showerhead 125 during processing and possibly result in particle generation. In some embodiments, the overall outer diameter 214 is about 17 inches.

In some embodiments, an overall height 216 of the showerhead is between about 1 inch and about 1.5 inches. The inventors have discovered that if the overall height 216 is greater than about 1.5 inches either the volume between the showerhead and the lid plate 170 is increased, which would negatively impact throughput and process time because of an additional volume that would need to be purged and pumped down, or the thickness of the central portion 204 is increased, which would negatively impact deposition uniformity because of a decreased distance from the showerhead 125 to the substrate 110. In some embodiments, the overall height 216 is about 1.14 inches.

In some embodiments, a vertical thickness 218 of the flange 210 is between about 0.5 inches and about 0.6 inches. The inventors have discovered that if the vertical thickness 218 is less than about 0.5 inches, a resulting gap would exist between the bottom of the showerhead 125 and the chamber liner 177, which would negatively impact throughput and process time because of an additional volume that would need to be purged and pumped down. If the vertical thickness 218 is greater than about 0.6 inches, the showerhead 125 may be damaged due to increased contact with the chamber liner 177. In some embodiments, the vertical thickness 218 is about 0.58 inches.

In some embodiments, a vertical distance 220 from a first uppermost surface of the flange 210 to a second uppermost surface of the annular stepped portion 212 is between about 0.5 inches and about 1 inch. The inventors have discovered that if the vertical distance 220 is smaller than about 0.5 inches, then the first seal 109 will be over-compressed, thus possibly causing damage to the first seal 109 and sticking of the first seal 109 to the showerhead 125. If the vertical distance 220 is larger then about 1 inch, then the first seal 109 will not be compressed enough to prevent a leakage of process gases out of the reaction zone 164. In some embodiments, the vertical distance 220 is about 0.78 inches.

In some embodiments, a thickness 222 of the central portion 204 is between about 0.2 inches and about 0.5 inches. The inventors have discovered that if the thickness 222 is less than about 0.2 inches, then insufficient choke of the process gases and possibly bowing of the central portion 204 may occur. If the thickness 222 is larger than about 0.5 inches, then the flow of process gas may be over-choked, thus negatively impacting deposition uniformity.

In some embodiments, a first inner diameter 224 of the annular stepped portion 212 is between about 12 inches and about 13 inches. The inventors have discovered that if the first inner diameter 224 is smaller than about 12 inches, then the showerhead 125 will have fewer apertures 126 and outermost ones of the apertures 126 will not be at or outside of the substrate 110. If the first inner diameter 224 is larger than about 13 inches, then an additional volume of process gas will exist radially outward of the outermost ones of the apertures 126, thus negatively impacting throughput and processing time because of the increased time required to purge and pump down the additional volume. In some embodiments, the first inner diameter 224 is about 12.25 inches.

In some embodiments, a second inner diameter 226 of the annular wall 208 is between about 12.5 inches and about 13.5 inches. The inventors have discovered that if the second inner diameter 226 is smaller than about 12.15 inches, then the annular stepped portion 212 would be smaller, resulting in the drawbacks explained above with respect to the size of the first inner diameter 224. If the second inner diameter 226 is larger than about 13.5 inches, then an additional volume of process gas will exist radially outward of the outermost ones of the apertures 126, thus negatively impacting throughput and processing time because of the increased time required to purge and pump down the additional volume. In some embodiments, the second inner diameter 226 is about 12.6 inches.

In some embodiments, an outer diameter 228 of a lowermost surface of the central portion is between about 13.5 inches and about 14.5 inches. The inventors have discovered that if the outer diameter 228 is smaller than about 13.5 inches, then the showerhead 125 will have fewer apertures 126 and outermost ones of the apertures 126 will not be at or outside of the substrate 110. If the outer diameter 228 is larger than about 14.5 inches, then the time required to pump the process chamber 100 down will increase, thus negatively impacting throughput and process time. In some embodiments, the outer diameter 228 is about 13.8 inches.

In some embodiments, a radial distance 230 between the outermost ones of the plurality of apertures 126 and an inner edge of the annular stepped portion 212 is between about 0 inches (i.e., the outermost ones of the plurality of apertures are disposed at the inner edge of the annular stepped portion 212) and about 0.1 inches. The inventors have discovered that the radial distance 230 functions as dead space in which process gas can recirculate, resulting in increased difficulty in pumping and/or purging the dead space. In some embodiments, the radial distance 230 is about 0.06 inches.

FIG. 3B is a close-up of section 3B in FIG. 3A illustrating of one of the plurality of apertures 126. In some embodiments, each of the plurality of apertures 126 is a countersunk hole having a countersink portion 302 and a hole portion 304. The countersink portion 302 is formed through the lowermost surface of the central portion 204 and has a depth 306 between about 1 to 2 times a hole diameter 308 of the hole portion. In some embodiments, the depth 306 is about 0.06 inches and the hole diameter 308 is about 0.04 inches. The inventors have discovered that if the depth 306 is deeper than about 2 times the hole diameter 308, then the flow of process gas through the showerhead 125 will not be sufficiently choked. As a result, deposition uniformity will be negatively impacted because the pressure above the showerhead will not be uniform and more deposition will occur at the center of the substrate 110 since the central portion of the showerhead 125 will be the path of least resistance to the flow of process gas. Conversely, if the depth 306 is less than about 1× the hole diameter 308, then gas flowing through each aperture 126 would quickly expand after exiting the aperture, resulting in cooling of the gas and particle generation. In addition, an imprint of the pattern of the plurality of apertures 126 would result on the substrate 110.

In some embodiments, a countersink angle 310 of the countersink portion is between about 25 degrees and about 45 degrees. If the countersink angle 310 is smaller than about 25 degrees or larger than about 45 degrees, then the resulting flow of gas through the aperture 126 would be similar to the flow of gas through a through hole (i.e., quick expansion of gas, as explained above). In some embodiments, the countersink angle is about 37 degrees.

In some embodiments, the hole diameter 308 is between about 0.012 inches and about 0.06 inches. The inventors have discovered that if the hole diameter 308 is less than about 0.012 inches, then the flow of process gas will be over-choked. Conversely, if the hole diameter 308 is larger than about 0.06 inches, then the flow of gas will not be sufficiently choked. For example, in embodiments in which the showerhead 125 is disposed beneath a funnel lid (e.g., chamber lid assembly 132) the large apertures will not adequately mitigate the issues associated with circular flow discussed above. In some embodiments, the hole diameter is about 0.04 inches.

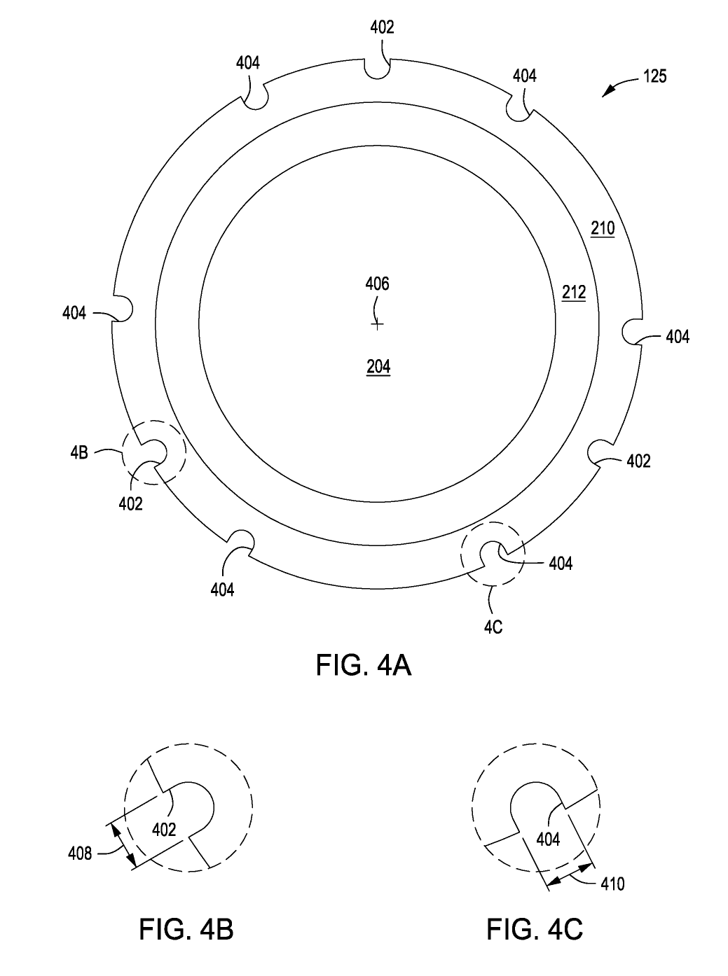

FIG. 4A depicts a schematic top view of the showerhead 125 in accordance with some embodiments of the present disclosure. The apertures 126 have been omitted from FIG. 4A for clarity. FIGS. 4B and 4C depict close-up views of sections 4B and 4C, respectively. In some embodiments, the showerhead 125 includes a plurality of positioning features 402 arranged about a central axis 406 of the showerhead 125. The plurality of positioning features 402 are formed in a periphery of the flange 210 and are configured to receive a corresponding plurality of alignment elements (not shown) such as, for example, alignment pins of a process chamber (e.g., process chamber 100) in which the showerhead 125 is installed. Additionally, the plurality of positioning features 402 are configured to allow for thermal expansion of the showerhead 125. In some embodiments, the plurality of positioning features 402 are arranges axissymmetrically about the central axis 406 to ensure equal thermal expansion of the showerhead 125 in all directions. In some embodiments, the plurality of positioning features 402 may alternatively be arranges asymmetrically about the central axis 406 to ensure proper positioning of the showerhead 125. As shown in FIGS. 4A and 4B, the plurality of positioning features 402 may be a plurality of first slots having a first width 408. In some embodiments, the first width 408 is between about 0.0001 inches and about 0.005 inches. The inventors have discovered that if the first width 408 is smaller than about 0.0001 inches, then rubbing occurs between walls of the first slots and their corresponding chamber alignment elements, resulting in particle generation. Conversely, if the first width 408 is larger than about 0.005 inches, the showerhead 125 would not be properly aligned because concentricity with the process chamber would be lost.

The showerhead 125 also includes a plurality of coupling features 404 arranged about the central axis 406 and formed in the periphery of the flange 210. The plurality of coupling features 404 are configured to receive a corresponding plurality of fixation elements (not shown) such as, for example, screws or bolts to couple the showerhead 125 to the process chamber (e.g., process chamber 100). The plurality of coupling features 404 are also configured to allow for thermal expansion of the showerhead 125. As shown in FIGS. 4A and 4C, the plurality of coupling features 404 may be a plurality of second slots having a second width 410. In some embodiments, the plurality of second slots may include between 3 and 24 slots. The inventors have discovered that having more than 24 slots may result in particle generation. In some embodiments, the showerhead 125 may include 6 second slots. In some embodiments, the second width is between about 0.23 inches and about 0.24 inches.

Returning to FIG. 1, in a processing operation, substrate 110 is delivered to process chamber 100 through slit valve 108 by a robot (not shown). Substrate 110 is positioned on substrate support 112 through cooperation of lift pins 120 and the robot. Substrate support 112 raises substrate 110 into close opposition to a lower surface of the showerhead 125. A first gas flow may be injected into gas dispersion channel 134 of process chamber 100 by the gas delivery system 130 together or separately (i.e., pulses) with a second gas flow. The first gas flow may contain a continuous flow of a purge gas from a purge gas source and pulses of a reactant gas from a reactant gas source or may contain pulses of a reactant gas from the reactant gas source and pulses of a purge gas from the purge gas source. The second gas flow may contain a continuous flow of a purge gas from a purge gas source and pulses of a reactant gas from a reactant gas source or may contain pulses of a reactant gas from a reactant gas source and pulses of a purge gas from a purge gas source.

Circular gas flow travels through gas dispersion channel 134 and subsequently through the plurality of apertures 126 in the showerhead 125. The gas is then deposited on the surface of substrate 110. The lower surface 160 of chamber lid assembly 132, which is downwardly sloping, helps reduce the variation of the velocity of the gas flow across the surface of showerhead 125. Excess gas, by-products, etc. flow into the pumping channel 179 and are then exhausted from process chamber 100

While the foregoing is directed to some embodiments of the present disclosure, other and further embodiments may be devised without departing from the basic scope thereof.

What is claimed is:

1. A showerhead, comprising:
a body having a central portion and an outer portion, wherein the outer portion includes an annular wall extending upward from the central portion and a flange extending radially outward from the annular wall;
a plurality of apertures disposed through the central portion;
an annular stepped portion disposed radially outward of outermost ones of the plurality of apertures and radially inward of the outer portion;
a plurality of positioning features arranged about a central axis of the showerhead and formed in a periphery of the flange, wherein the plurality of positioning features are configured to receive a corresponding plurality of alignment features of a process chamber in which the showerhead is installed, and wherein the plurality of positioning features are configured to allow for thermal expansion of the showerhead; and
a plurality of coupling features arranged about the central axis and formed in the periphery of the flange, wherein the plurality of coupling features are configured to receive a corresponding plurality of fixation elements to couple the showerhead to the process chamber, and wherein the plurality of coupling features are configured to allow for thermal expansion of the showerhead.

2. The showerhead of claim 1, wherein the showerhead is formed of one of aluminum, stainless steel, or a ceramic.

3. The showerhead of claim 1, wherein an overall outer diameter of the showerhead is between about 16 inches and about 17.5 inches.

4. The showerhead of claim 1, wherein an overall height of the showerhead is between about 1 inch and about 1.5 inches.

5. The showerhead of claim 1, wherein a vertical thickness of the flange is between about 0.5 inches and about 0.6 inches.

6. The showerhead of claim 1, wherein a vertical distance from a first uppermost surface of the flange to a second uppermost surface of the annular stepped portion is between about 0.5 inches and about 1 inch.

7. The showerhead of claim 1, wherein a thickness of the central portion is between about 0.2 inches and about 0.5 inches.

8. The showerhead of claim 1, wherein a first inner diameter of the annular stepped portion is between about 12 inches and about 13 inches.

9. The showerhead of claim 1, wherein a second inner diameter of the annular wall is between about 12.5 inches and about 13.5 inches.

10. The showerhead of claim 1, wherein an outer diameter of a lowermost surface of the central portion is between about 13.5 inches and about 14.5 inches.

11. The showerhead of claim 1, wherein the plurality of positioning features is a plurality of first slots.

12. The showerhead of claim 11, wherein the plurality of first slots is three second slots arranged axissymmetrically about the central axis and each having a first width between about 0.0001 inches and about 0.005 inches.

13. The showerhead of claim 1, wherein the plurality of coupling features is a plurality of second slots.

14. The showerhead of claim 13, wherein the plurality of second slots is between 3 and 24 slots, each having a second width between about 0.23 inches and about 0.24 inches.

15. The showerhead of claim 1, wherein each of the plurality of apertures is a countersunk hole having a countersink portion and a hole portion, wherein the countersink portion is formed through a lowermost surface of the central portion, wherein a depth of the countersink portion is between about 1 to 2 times a hole diameter of the hole portion, and wherein a countersink angle of the countersink portion is between about 25 degrees and about 45 degrees.

16. The showerhead of claim 15, wherein the hole diameter is between about 0.012 inches and about 0.06 inches.

17. The showerhead of claim 1, wherein the plurality of apertures is between about 1,000 and about 3,000 apertures, and wherein the outermost ones of the plurality of apertures are disposed at or outside of a diameter of a substrate to be processed using the showerhead.

18. The showerhead of claim 1, wherein a radial distance between the outermost ones of the plurality of apertures and an inner edge of the annular stepped portion is between about 0 inches and about 0.1 inches.

19. A showerhead, comprising:
a body having a central portion and an outer portion, wherein the outer portion includes an annular wall extending upward from the central portion and a flange extending radially outward from the annular wall;
a plurality of apertures disposed through the central portion;
an annular stepped portion disposed radially outward of outermost ones of the plurality of apertures and radially inward of the outer portion;
a plurality of positioning features arranged about a central axis of the showerhead and formed in a periphery of the flange, wherein the plurality of positioning features are configured to receive a corresponding plurality of alignment features of a process chamber in which the showerhead is installed, and wherein the plurality of positioning features are configured to allow for thermal expansion of the showerhead; and
a plurality of coupling features arranged about the central axis and formed in the periphery of the flange, wherein the plurality of coupling features are configured to receive a corresponding plurality of fixation elements to couple the showerhead to the process chamber, and wherein the plurality of coupling features are configured to allow for thermal expansion of the showerhead,
wherein an overall outer diameter of the showerhead is between about 16 inches and about 17.5 inches,
wherein an overall height of the showerhead is between about 1 inch and about 1.5 inches,
wherein a vertical thickness of the flange is between about 0.5 inches and about 0.6 inches,
wherein a vertical distance from a first uppermost surface of the flange to a second uppermost surface of the annular stepped portion is between about 0.5 inches and about 1 inch, and
wherein a thickness of the central portion is between about 0.2 inches and about 0.5 inches.

20. A showerhead, comprising:
a body having a central portion and an outer portion, wherein the outer portion includes an annular wall extending upward from the central portion and a flange extending radially outward from the annular wall;
a plurality of apertures disposed through the central portion;
an annular stepped portion disposed radially outward of outermost ones of the plurality of apertures and radially inward of the outer portion;
a plurality of positioning features arranged about a central axis of the showerhead and formed in a periphery of the flange, wherein the plurality of positioning features are configured to receive a corresponding plurality of alignment features of a process chamber in which the showerhead is installed, and wherein the plurality of positioning features are configured to allow for thermal expansion of the showerhead; and
a plurality of coupling features arranged about the central axis and formed in the periphery of the flange, wherein the plurality of coupling features are configured to receive a corresponding plurality of fixation elements to couple the showerhead to the process chamber, and wherein the plurality of coupling features are configured to allow for thermal expansion of the showerhead,
wherein an overall outer diameter of the showerhead is between about 16 inches and about 17.5 inches,
wherein an overall height of the showerhead is between about 1 inch and about 1.5 inches,
wherein a vertical thickness of the flange is between about 0.5 inches and about 0.6 inches,
wherein a vertical distance from a first uppermost surface of the flange to a second uppermost surface of the annular stepped portion is between about 0.5 inches and about 1 inch,
wherein a thickness of the central portion is between about 0.2 inches and about 0.5 inches,
wherein a first inner diameter of the annular stepped portion is between about 12 inches and about 13 inches,
wherein a second inner diameter of the annular wall is between about 12.5 inches and about 13.5 inches, and
wherein an outer diameter of a lowermost surface of the central portion is between about 13.5 inches and about 14.5 inches.
